(19) United States
(12) Patent Application Publication
(10) Pub. No.: US 2025/0374497 A1
(43) Pub. Date: Dec. 4, 2025

(54) METHOD AND SYSTEM FOR EXTENDING CONTINUITY OF A PLURALITY OF COMMUNICATION BUSSES BETWEEN ELECTRONIC DEVICES MOUNTED TO A DIN RAIL

(71) Applicant: Honeywell International Inc., Charlotte, NC (US)

(72) Inventors: Cary Leen, Hammond, WI (US); Graham Lewry, East Sussex (GB); Kelvin Towler, Barnham (GB); Wei Guo, Beijing (CN); Yong Mu, Beijing (CN); Martin Back, West Sussex (GB); Hang Su, Chongqing (CN); Michael Zheng, Beijing (CN)

(21) Appl. No.: 18/875,034

(22) PCT Filed: Jun. 13, 2022
(86) PCT No.: PCT/CN2022/098385

§ 371 Date: Dec. 13, 2024

(51) Int. Cl. H05K 9/00; H01R 13/24

(52) U.S. Cl. CPC H05K 9/0081; H01R 13/24

(57) ABSTRACT

An electronic device is configured for use with neighboring electronic devices mounted on a DIN rail to control at least part of a Building Management System (BMS). The electronic device includes a housing and a plurality of communication passthroughs extending between two opposing sides of the housing. Each of the plurality of communication passthroughs include a contact disposed on each of the two opposing side of the housing, wherein each of the contacts is configured to electrically and mechanically couple to a corresponding contact of a neighboring electronic device on the DIN rail. A first subset of the plurality of communication passthroughs collectively pass a first communication bus between the two opposing sides of the housing and a second subset of the plurality of communication passthroughs collectively pass a second communication bus between the two opposing sides of the housing.

The present application claims priority to PCT International Application No. PCT/CN2022/098385, filed on Jun. 13, 2022, entitled “METHOD AND SYSTEM FOR EXTENDING CONTINUITY OF A PLURALITY OF COMMUNICATION BUSSES BETWEEN ELECTRONIC DEVICES MOUNTED TO A DIN RAIL”, which is incorporated herein by reference.

### TECHNICAL FIELD

The present disclosure relates to electrical connectors, and more particularly, to electrical connectors for electrically connecting two or more controllers and/or other devices in order to pass along a communication bus between two or more controllers and/or other devices.

### BACKGROUND

Automation, process control and other systems often use various controllers and/or other devices. In some instances, it is desirable to electrically connect two or more of the controllers and/or other devices, including maintaining or passing along one or more communication busses between the multiple devices. This is often accomplished using wires or cables. What would be desirable is an improved electrical connector for electrically connecting two or more controllers and/or other devices.

### SUMMARY

This disclosure relates to electrical connectors, and more particularly, to electrical connectors for electrically connecting two or more controllers and/or other devices in order to pass along a plurality of communication busses between two or more controllers and/or other devices.

An example may be found in an electronic device that is configured for use with neighboring electronic devices mounted on a DIN rail to control at least part of a Building Management System (BMS). The electronic device includes a housing and a plurality of communication passthroughs extending between two opposing sides of the housing. Each of the plurality of communication passthroughs include a contact disposed on each of the two opposing sides of the housing, wherein each of the contacts is configured to electrically and mechanically couple to a corresponding contact of a neighboring electronic device on the DIN rail. A first subset of the plurality of communication passthroughs collectively pass a first communication bus between the two opposing sides of the housing and a second subset of the plurality of communication passthroughs collectively pass a second communication bus between the two opposing sides of the housing.

Another example may be found in a method for mounting a plurality of building management system (BMS) components on a DIN rail. The illustrative method includes mounting a first BMS component on the DIN rail. The first BMS component includes a housing and plurality of contact pairs, wherein each of the plurality of contact pairs are electrically connected together and are positioned on two opposing sides of the housing, wherein each of the contacts is configured to electrically and mechanically couple to a corresponding contact of an adjacently mounted BMS component on the DIN rail. A second BMS component is mounted on the DIN rail with a first side of the second BMS component adjacent a second side of first BMS component. The second BMS component including a housing and plurality of contact pairs, wherein each of the plurality of contact pairs are electrically connected together and are positioned on two opposing sides of the housing of the second BMS component, wherein each of the contacts on the first side of the second BMS component is configured to electrically and mechanically couple to a corresponding contact on the second side of the first BMS component. A first subset of the plurality of contact pairs of the first BMS component correspond to a first communication bus that is passed between the first BMS component and the second BMS component. A second subset of the plurality of contact pairs of the first BMS component correspond to a second communication bus that is passed between the first BMS component and the second BMS component.

Another example may be found in an electronic device that is configured for use with neighboring electronic devices mounted on a DIN rail in order to maintain a plurality of communication buses through the electronic device. The electronic device includes a housing configured to be mountable next to a neighboring electronic device on a DIN rail. A plurality of power passthroughs extend through the housing and include contacts disposed on two opposing sides of the housing such that the contacts are configured to electrically coupled with contacts disposed on one or more sides of a neighboring electronic device in order to extend power between the electronic device and the neighboring electronic device. A plurality of communication passthroughs extend through the housing and include contacts disposed on the two opposing sides of the housing such that the contacts are configured to electrically couple with contacts disposed on one or more sides of the neighboring electronic device in order to maintain a plurality of communication busses between the electronic device the neighboring electronic device.

The preceding summary is provided to facilitate an understanding of some of the features of the present disclosure and is not intended to be a full description. A full appreciation of the disclosure can be gained by taking the entire specification, claims, drawings, and abstract as a whole.

### BRIEF DESCRIPTION OF THE DRAWINGS

The disclosure may be more completely understood in consideration of the following description of various illustrative embodiments of the disclosure in connection with the accompanying drawings, in which:

Figure is a perspective view of an illustrative electronic device;

FIG. 2 is a perspective view of an illustrative electronic device;

FIG. 3 is a front schematic view of several illustrative electronic devices mounted

on a first DIN rail and a second DIN rail;

FIG. 4 is a front schematic view of several illustrative electronic devices mounted on a first DIN rail and a second DIN rail;

FIG. 5 is a schematic view of several illustrative electronic devices mounted together;

FIG. 6 is a schematic block diagram showing several communication protocols extending through a plurality of electronic devices;

FIG. 7 is a flow diagram showing an illustrative method for mounting a plurality of BMS components on a DIN rail;

FIG. 8 is a flow diagram showing an illustrative method for mounting a plurality of BMS components on a DIN rail;

FIG. 9 is a flow diagram showing an illustrative method for mounting a plurality of BMS components on a DIN rail;

FIG. 10 a flow diagram showing an illustrative method for mounting a plurality of BMS components on a DIN rail;

FIG. 11 a flow diagram showing an illustrative method for mounting a plurality of BMS components on a DIN rail;

FIGS. 12A and 12B are flow diagrams that together show an illustrative method for mounting a plurality of BMS components on a DIN rail;

FIG. 13 is an electrical schematic diagram of a wiring adapter that extends the continuity of a first communication bus through touch flake pairs while providing wiring terminals to access the first communication bus;

FIG. 14 is an electrical schematic diagram of the wiring adapter that extends the continuity of a second communication bus through touch flake pairs while providing wiring terminals to access the second communication bus;

FIG. 15 is a first side perspective of an illustrative wiring adaptor;

FIG. 16 is a second side perspective view of the illustrative wiring adaptor of FIG. 15;

FIG. 17 is a partially exploded perspective view of the illustrative wiring adaptor of FIG. 15; and

FIG. 18 is a perspective view of the illustrative wiring adaptor of FIG. 15, with several components removed to reveal internal details.

While the disclosure is amenable to various modifications and alternative forms, specifics thereof have been shown by way of example in the drawings and will be described in detail. It should be understood, however, that the intention is not to limit aspects of the disclosure to the particular illustrative embodiments described. On the contrary, the intention is to cover all modifications, equivalents, and alternatives falling within the spirit and scope of the disclosure.

### DESCRIPTION

The following description should be read with reference to the drawings wherein like reference numerals indicate like elements. The drawings, which are not necessarily to scale, are not intended to limit the scope of the disclosure. In some of the figures, elements not believed necessary to an understanding of relationships among illustrated components may have been omitted for clarity.

All numbers are herein assumed to be modified by the term “about”, unless the content clearly dictates otherwise. The recitation of numerical ranges by endpoints includes all numbers subsumed within that range (e.g., 1 to 5 includes 1, 1.5, 2, 2.75, 3, 3.80, 4, and 5).

As used in this specification and the appended claims, the singular forms “a”, “an”, and “the” include the plural referents unless the content clearly dictates otherwise. As used in this specification and the appended claims, the term “or” is generally employed in its sense including “and/or” unless the content clearly dictates otherwise.

It is noted that references in the specification to “an embodiment”, “some embodiments”, “other embodiments”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is contemplated that the feature, structure, or characteristic may be applied to other embodiments whether or not explicitly described unless clearly stated to the contrary.

A variety of control systems, including building management systems, include controllers and other electronic devices. A building management system (BMS) may include any of a security system, a lighting system or a heating, ventilating and air conditioning (HVAC) system. A BMS may include combinations of these systems. In some instances, a controller may be used in combination with other electronic devices such as IO modules that provide additional opportunities for wiring connections between various components of the BMS and the controller or controllers operating the BMS. In some cases, the other electronic devices, such as IO modules, are both electrically and mechanically coupled to the controller or controllers operating the BMS. Large BMS systems may include a large number of individual components, and thus may employ a plurality of IO modules that are electrically coupled to the controller or controllers.

In some cases, the electronic devices, such as controllers, IO modules and even communication modules, may be coupled together along one or more DIN rails. In some cases, the electronic devices may be coupled together along two or more DIN rails because not all of the electronic devices will fit on a single DIN rail, or some of the electronic devices may be disposed on a DIN rail at a first location and some of the electronic devices may be disposed on a DIN rail at a second location. The first and second locations may be within the same electrical panel, for example. In some cases, the first and second locations may be within different rooms or spaces within a facility. While BMS is used as an example, it is contemplated that the present disclosure is equally applicable to other applications, such as industrial process control, automotive, military and other applications.

FIG. 1 is a perspective view of an illustrative electronic device 10 having a housing 12. The illustrative electronic device 10 may be a controller, an IO device such as an IO module, or any other electronic device. The features described herein may be applied to controllers, process devices, sensors, etc. The illustrative housing 12 includes a front side 14, a back side 16, and at least a first side 18 and a second opposing side 20. The first and second sides 18, 20 may each extend from or between the front 14 to the back 16. The back 16 may be configured to be releasably securable to a DIN rail, for example. The housing 12 may further include a top 22 and an opposing bottom 24. The top and bottom 22, 24 may extend from or between the first and second sides 18, 20. The use of the terms “front”, “back”, “first”, “second”, “top”, and “bottom” are not intended to limit the electronic device 10 to a particular orientation, but rather facilitate discussion of relative orientation. Further, the housing 12 is not limited to a rectangular or generally rectangular structure. Other shapes may be used for the housing 12, as desired.

As can be seen on the first side 18 of the housing 12, the electronic device 10 includes a first set of contacts 26, individually labeled as 26a, 26b and 26c. The electronic device 10 also includes a second set of contacts 28, individually labeled as 28a, 28b, 28c and 28d. While the first set of contacts 26 is shown as having a total of three contacts 26 and the second set of contacts 28 is shown as having a total of four contacts 28, it will be appreciated that in some cases, the first set of contacts 26 may include more than three contacts 26 or fewer than three contacts 26, and/or the second set of contacts 28 may include more than four contacts 28 or fewer than four contacts 28. In some cases, the first set of contacts 26 and the second set of contacts 28 may not be separated out as shown, but may be grouped together on the first side 18 of the housing 12.

The first set of contacts 26 and the second set of contacts 28 may be configured to provide electrical and/or mechanical connections between the electronic device 10 and another electronic device 10 that is positioned adjacent the electronic device 10. While the first set of contacts 26 is visible only on the first side 18 of the housing 12, and the second set of contacts 28 is visible only on the first side 18 of the housing 12 in FIG. 1, in some cases the electronic device 10 includes a corresponding first set of contacts and a corresponding second set of contacts disposed on the second side 20 of the housing 12. The electronic device 10 may include passthroughs that extend between the contacts 26 disposed on the first side 18 of the housing 12 to the corresponding contacts disposed on the second side 20 of the housing 12. The electronic device 10 may include passthroughs that extend between the contacts 28 disposed on the first side 18 of the housing 12 to the corresponding contacts disposed on the second side 20 of the housing 12. Each passthrough may connect a corresponding pair of contact, with one contact of the contact pair situated and exposed on the first side 18 of the housing and the other contact of the contact pair situated and exposed on the second side 20 of the housing 12.

In some cases, at least some of the passthroughs may include electrical conductors or members that extend between the contacts 26, 28 on the first side 18 of the housing 12 to the corresponding contacts disposed on the second side 20 of the housing 12. In some cases, at least some of the passthroughs may include electrical traces disposed on a printed circuit board, and in some instances may include additional electrical components that form a part of an electrical path between each of the contacts 26, 28 on the first side 18 of the housing 12 to the corresponding contacts disposed on the second side 20 of the housing 12.

In some instances, the first set of contacts 26 and the second set of contacts 28, as well as the corresponding contacts on the opposing side of the housing 12, may be considered as being spring contacts that provide both an electrical coupling and a mechanical coupling with another device placed in close proximity along either the first side 18 of the housing 12 or the second side 20 of the housing 12. In some instances, each of the first set of contacts 26, as well as the corresponding contacts on the opposing side of the housing 12 and the electrical traces or other components extending therebetween, may be considered as forming power passthroughs. Each of the second set of contacts 28, as well as the corresponding contacts on the opposing side of the housing 12 and the electrical traces or other components extending therebetween, may be considered as forming communication passthroughs. The power passthroughs may be configured to be able to pass power between adjacent devices through the power passthroughs. The power passthroughs may extend the continuity of power between adjacent devices through the electronic device 10. Likewise, the communication passthroughs may be configured to extend the continuity of one or more communication busses between adjacent devices through the electronic device 10.

While not explicitly shown, the first set of contacts 26 and the second set of contacts 28 may be male/female type plug contacts, or any other suitable contact type. In some cases, the first set of contacts 26 and the second set of contacts 28 on the first side 18 of the housing 12 are female plug type contacts and the first set of contacts 26 and the second set of contacts 28 on the second side 20 of the housing 12 may be male plug type contacts. In this configuration, the male plug type contacts on the second side 20 of a first device may plug into the female plug type contacts on the first side 18 of a second adjacent device, thereby forming a connection therebetween. Likewise, the male plug type contacts on the second side 20 of a second device may plug into the female plug type contacts on the first side 18 of a third device, thereby forming a connection. These are just some example connections types between adjacent or neighboring devices that may be employed.

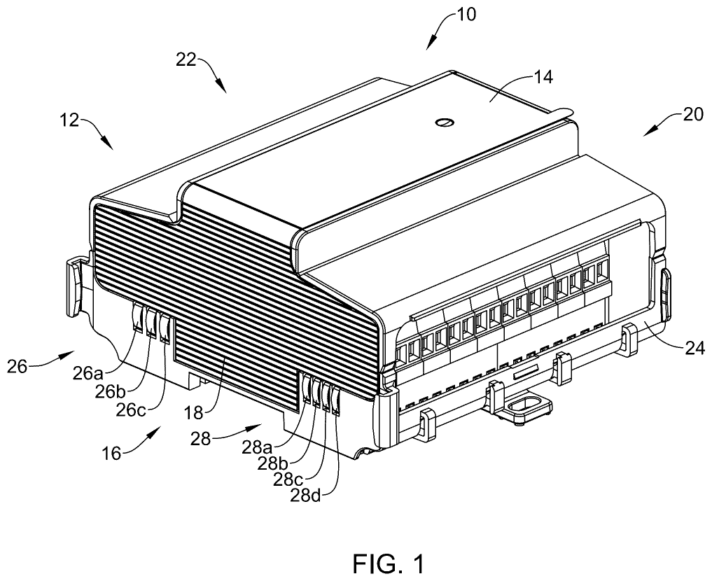

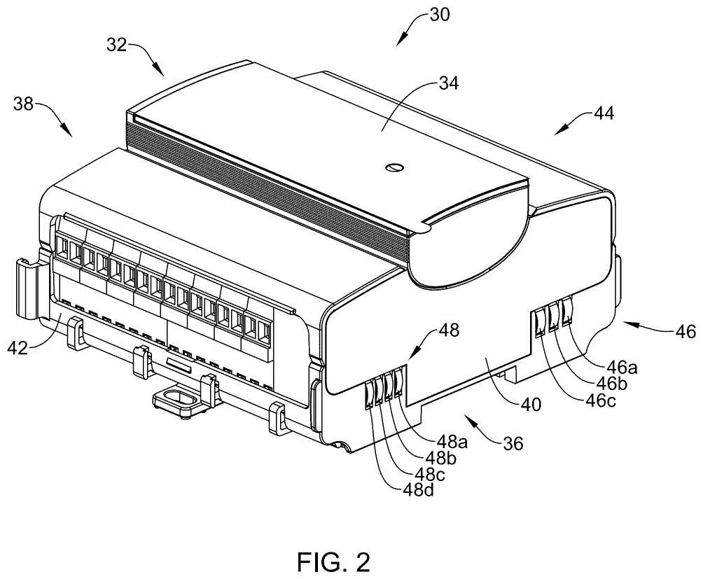

FIG. 2 is a perspective view of an illustrative electronic device 30 having a housing 32. The illustrative electronic device 30 may be a controller, an IO device such as an IO module, or any other electronic device. The features described herein may be applied to controllers, process devices, sensors, etc. The illustrative housing 32 includes a front side 34, a back side 36, and at least a first side 38 and a second opposing side 40. While the electronic device 10 of FIG. 1 is oriented such that the first side 18 of the housing 12 is visible, in FIG. 2 the electronic device 30 is oriented such that the second side 40 is visible. It will be appreciated that features shown on the first side 18 of the housing 12 of FIG. 1, such as but not limited to the first set of contacts 26 and the second set of contacts 28, may be repeated on the second side 20 of the housing 12 of FIG. 1. Moreover, features shown on the second side 40 of the housing 32, such as but not limited to the first set of contacts 46 and the second set of contacts 48, to be discussed, may be repeated on the first side 38 of the housing 32. In some cases, the electronic device 30 of FIG. 2 represents a different view of the electronic device 10 of FIG. 1, explicitly showing the second side 20 of the electronic device 10 of FIG. 1.

The first and second sides 38, 40 shown in FIG. 2 may each extend from or between the front 34 to the back 36. The back 36 may be configured to be releasably securable to a DIN rail, for example. The housing 32 may further include a top 42 and an opposing bottom 44. The top and bottom 42, 44 may extend from or between the first and second sides 38, 40. The use of the terms “front”, “back”, “first”, “second”, “top”, and “bottom” are not intended to limit the electronic device 30 to a particular orientation, but rather facilitate discussion of relative orientation. Further, the housing 32 is not limited to a rectangular or generally rectangular structure. Other shapes may be used for the housing 32, as desired.

As can be seen on the second side 40 of the housing 32, the electronic device 30 includes a first set of contacts 46, individually labeled as 46a, 46b and 46c. The electronic device 30 also includes a second set of contacts 48, individually labeled as 48a, 48b, 48c and 48d. While the first set of contacts 46 is shown as having a total of three contacts 46 and the second set of contacts 48 is shown as having a total of four contacts 48, it will be appreciated that in some cases, the first set of contacts 46 may include more than three contacts 46 or fewer than three contacts 46, and/or the second set of contacts 48 may include more than four contacts 48 or fewer than four contacts 48. In some cases, the first set of contacts 46 and the second set of contacts 48 may not be separated out as shown, but may be grouped together on the second side 40 of the housing 32.

The first set of contacts 46 and the second set of contacts 48 may be configured to provide an electrical connection and in some cases a mechanical connection between the electronic device 30 and another electronic device 30 that is positioned adjacent the electronic device 30. While the first set of contacts 46 is visible only on the second side 40 of the housing 32, and the second set of contacts 48 is visible only on the second side 40 of the housing 32, in some cases the electronic device 30 includes a corresponding first set of contacts and a corresponding second set of contacts disposed on the first side 38 of the housing 32.

The electronic device 30 may include passthroughs that extend between the contacts 46 disposed on the second side 40 of the housing 32 to the corresponding contacts disposed on the first side 38 of the housing 32. The electronic device 30 may include passthroughs that extend between the contacts 48 disposed on the second side 40 of the housing 32 to the corresponding contacts disposed on the first side 38 of the housing 32.

In some cases, at least some of the passthroughs may include electrical conductors or members that extend between the contacts 46, 48 on the second side 40 of the housing 32 to the corresponding contacts disposed on the first side 38 of the housing 32. In some cases, at least some of the passthroughs may include electrical traces disposed on a printed circuit board, and in some instances may include additional electrical components that form a part of an electrical path between each of the contacts 46, 48 on the second side 40 of the housing 32 to the corresponding contacts disposed on the first side 38 of the housing 32.

In some instances, the first set of contacts 46 and the second set of contacts 48, as well as the corresponding contacts on the opposing side of the housing 32, may be considered as being spring contacts that provide both an electrical coupling and a mechanical coupling with another device placed in close proximity along either the first side 38 of the housing 32 or the second side 40 of the housing 32. In some instances, each of the first set of contacts 46, as well as the corresponding contacts on the opposing side of the housing 32 and the electrical traces or other components extending therebetween, may be considered as forming power passthroughs. Each of the second set of contacts 48, as well as the corresponding contacts on the opposing side of the housing 32 and the electrical traces or other components extending therebetween, may be considered as forming communication passthroughs. The power passthroughs may be configured to be able to pass power between adjacent devices through the power passthroughs. The power passthroughs may extend the continuity of power between adjacent devices through the electronic device 10. Likewise, the communication passthroughs may be configured to extend the continuity of one or more communication busses between adjacent devices through the electronic device 10.

While not explicitly shown, the first set of contacts 26 and the second set of contacts 28 may be male/female type plug contacts, or any other suitable contact type. In some cases, the first set of contacts 26 and the second set of contacts 28 on the first side 18 of the housing 12 are female plug type contacts and the first set of contacts 26 and the second set of contacts 28 on the second side 20 of the housing 12 may be male plug type contacts. In this configuration, the male plug type contacts on the second side 20 of a first device may plug into the female plug type contacts on the first side 18 of a second adjacent device, thereby forming a connection therebetween. Likewise, the male plug type contacts on the second side 20 of a second device may plug into the female plug type contacts on the first side 18 of a third device, thereby forming a connection. These are just some example connections types between adjacent or neighboring devices that may be employed.

Having contacts such as the contacts 26 (FIGS. 1) and 46 (FIG. 2) on either side of the electronic device 10, 30, with power passthroughs extending between the contacts 26 and the corresponding contacts on the opposing side, and extending between the contacts 46 and the corresponding contacts on the opposing side, means that the electronic device 10 and/or the electronic device 30 may be mounted adjacent to neighboring electronic devices (e.g. on a DIN rail), and the electronic device 10 and/or the electronic device 30 may extend the continuity of power across the electronic device 10, 30 to the adjacent devices. Having contacts 28 and 48 on either side of the electronic device 10, 30, with communication passthroughs extending between the contacts 28 and the corresponding contacts on the opposing side, and extending between the contacts 48 and the corresponding contacts on the opposing side, means that when the electronic device 10 and/or the electronic device 30 may be mounted adjacent to neighboring electronic devices (e.g. on a DIN rail), and the electronic device 10 and/or the electronic device 30 may extend the continuity of one or more communication busses across the electronic device 10, 30 to the adjacent devices.

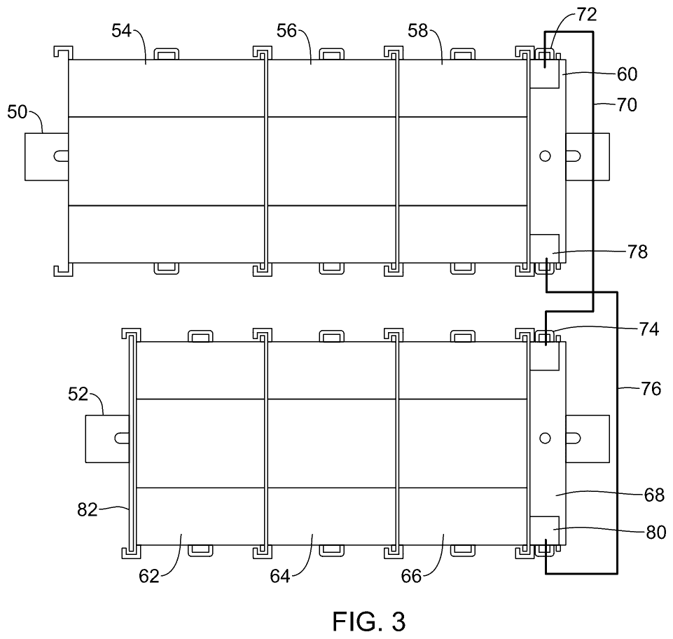

Electronic devices such as but not limited to the electronic device 10 and the electronic device 30 may be mounted, such as to a DIN rail, in any of a variety of different orders, and in a variety of combinations. FIG. 3 shows several electronic devices mounted on a first DIN rail 50 and several electronic devices mounted on a second DIN rail 52. The first DIN rail 50 includes a first electronic device 54, a second electronic device 56, a third electronic device 58 and a fourth electronic device 60. The second DIN rail 52 includes a fifth electronic device 62, a sixth electronic device 64, a seventh electronic device 66 and an eight electronic device 68. As an example, the first electronic device 54 may be a controller. The second electronics device 56, the third electronic device 58, the fifth electronic device 62, the sixth electronic device 64 and the seventh electronic device 66 may be considered to be examples of IO modules, which serve to provide additional wiring terminals for connecting peripherals to the controller 54.

The fourth electronic device 60 and the eighth electronic device 68 may be considered as being examples of wiring adaptors, which provide an ability to easily electrically couple to the electronic devices adjacent to them (such as the third electronic device 58 and the seventh electronic device 66, respectively) and to enable wires or other electrical conductors to easily be coupled to the wiring adaptor. The wiring adaptors may provide an easy way to provide continuity between power of the electronic devices disposed on the first DIN rail 50 to the devices disposed on the second DIN rail 52. Also, the wiring adaptors may provide an easy way to continue communication busses from the electronic devices disposed on the first DIN rail 50 to the devices disposed on the second DIN rail 52. In the example shown, an electrical conductor 70, which may include one, two, three or more distinct and electrically isolated electrical conductors (e.g. wires), has been extended from a wiring terminal 72 forming part of the fourth electronics device 60 to a wiring terminal 74 forming part of the eighth electronic device 68. In some cases, the wiring terminals 72 and 74 may be considered as being power terminals, and thus power from the electronic devices disposed on the first DIN rail 50 is easily continued to the electronic devices disposed on the second DIN rail 52. As such, and in some cases, a single power supply, such as a power supply of controller 54, may provide power to itself, electronic devices 56 and 58, and electronic devices 62, 54 and 66 through wiring adaptors 60 and 68.

Likewise, an electrical conductor 76, which may include one, two, three, four or more distinct and electrically isolated electrical conductors (e.g. wires), has been extended from a wiring terminal 78 forming part of the fourth electronic device 60 to a wiring terminal 80 forming part of the eighth electronic device 68. In some cases, the wiring terminals 78 and 80 may be considered as being the communication terminals, and thus one or more communication busses extending through the electronic devices disposed on the first DIN rail 50 are easily extended to the electronic devices disposed on the second DIN rail 52.

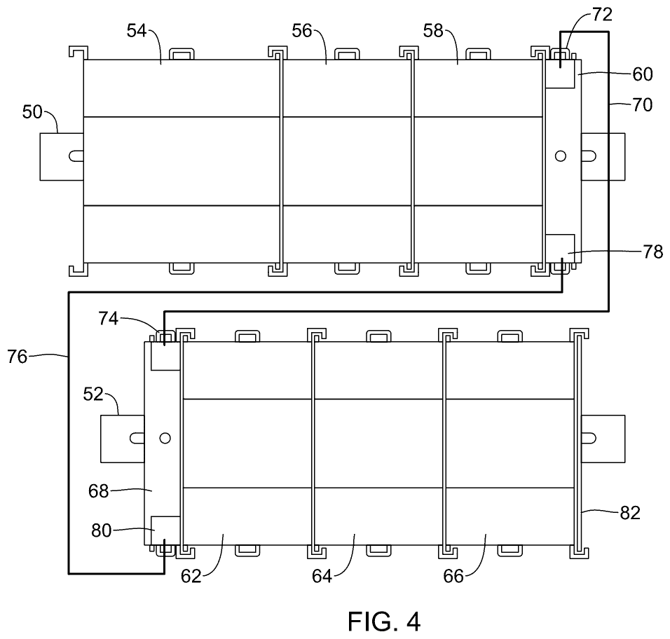

The electronic devices may be coupled together in any desired order. As an example, FIG. 4 shows the same electronic devices 54, 56, 58, 60, 62, 64, 66 and 68 disposed on the two DIN rails 50 and 52, respectively, but the eighth electronic device 68 has been moved to the opposite end of the DIN rail 52, such that the eighth electronic device 68 is now adjacent the fifth electronic device 62, rather than the seventh electronic device 66. Everything functions in the same way.

In some cases, a protective cover 82 may be used to electrically isolate the contacts 26, 28 (or the corresponding contacts on the opposing side) and/or the contacts 46, 48 (or the corresponding contacts on the opposing side) when those particular contacts are positioned such that they are not being used to couple to another neighboring electronic device. For example, in FIG. 3, a protective cover 82 is disposed adjacent the fifth electronic device 62 while in FIG. 4 the protective cover 82 is disposed adjacent the seventh electronic device 66. In some cases, the first electronic device 54, may only have contacts on one side of its housing, and thus has no need for a protective cover there. As will be discussed, the wiring adaptors shown as the fourth electronic device 60 and the eighth electronic device 68 may include a suitable protective cover to cover contacts that are not being used to couple to another neighboring electronic device (and thus exposed).

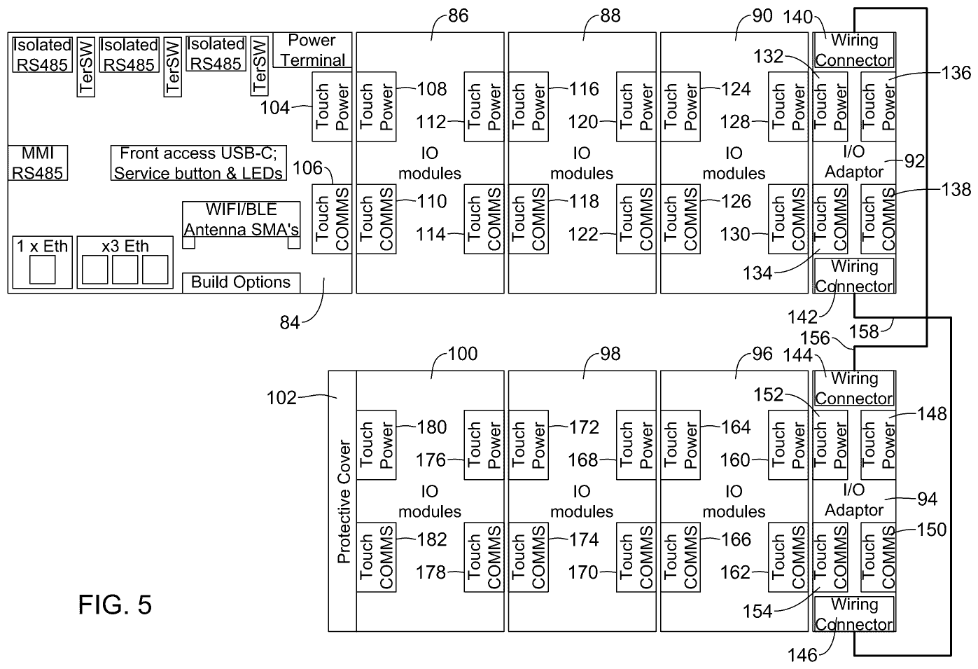

FIG. 5 is a schematic view of several illustrative electronic devices mounted together. In particular, FIG. 5 shows in combination an RS-485 equipped controller 84, an IO module 86, an IO module 88, an IO module 90 and a wiring adaptor 92 that are coupled together in a first row, such as on a first DIN rail, and a wiring adaptor 94, an IO module 96, an IO module 98 and an IO module 100 that are coupled together in a second row, such as on a second DIN rail. A protective cover 102 is disposed adjacent the IO module 100.

The RS-485 equipped controller 84 includes a set 104 of power contacts and a set 106 of communication contacts. The set 104 of power contacts may include three electrically isolated individual contacts such as spring contacts (or plug type contacts). The set 106 of communication contacts may include four electrically isolated individual contacts such as spring contacts (or plug type contacts). The IO module 86 may include a set 108 of power contacts that are configured to electrically couple with the set 104 of power contacts on the RS-485 equipped controller 84 as well as a set 110 of communication contacts that are configured to electrically couple with the set 106 of communication contacts on the RS-485 equipped controller 84, respectively. The IO module 86 may also include a second set 112 of power contacts and a second set 114 of communication contacts on an opposing side of the IO module 86 as shown. In the example shown, the set 108 of power contacts and the second set 112 of power contacts are electrically coupled together to pass power between the set 108 of power contacts and the second set 112 of power contacts. Also, the set 110 of communication contacts and the second set 114 of communication contacts are electrically coupled together to pass one or more communication busses between the set 110 of communication contacts and the second set 114 of communication contacts.

Similarly, the IO module 88 includes a set 116 of power contacts and a set 118 of communication contacts that are configured to electrically couple with the second set 112 of power contacts and the second set 114 of communication contacts of the IO module 86. The IO module 88 also includes a second set 120 of power contacts and a second set 122 of communication contacts. In the example shown, the set 116 of power contacts and the second set 120 of power contacts are electrically coupled together to pass power between the set 116 of power contacts and the second set 120 of power contacts. Also, the set 118 of communication contacts and the second set 122 of communication contacts are electrically coupled together to pass one or more communication busses between the set 118 of communication contacts and the second set 122 of communication contacts.

The IO module 90 includes a set 124 of power contacts and a set 126 of communication contacts that are configured to electrically couple with the second set 120 of power contacts and the second set 122 of communication contacts of the IO module 88. The IO module 90 also includes a second set 128 of power contacts and a second set 130 of communication contacts. In the example shown, the set 124 of power contacts and the second set 128 of power contacts are electrically coupled together to pass power between the set 124 of power contacts and the second set 128 of power contacts. Also, the set 126 of communication contacts and the second set 130 of communication contacts are electrically coupled together to pass one or more communication busses between the set 126 of communication contacts and the second set 130 of communication contacts.

The wiring adaptor 92 includes a set 132 of power contacts and a set 134 of communication contacts that are configured to electrically couple with the second set 128 of power contacts and the second set 130 of communication contacts, respectively, of the IO module 90. The wiring adaptor 92 also includes a second set 136 of power contacts and a second set 138 of communication contacts that may be used if the wiring adaptor 92 was mounted with another electronic device (not shown) on the right-hand side (in the illustrated orientation) of the wiring adaptor 92. The illustrative wiring adaptor 92 further includes a wiring terminal block 140 that is electrically coupled with the set 132 of power contacts and the second set 136 of power contacts. In the example shown, the set 132 of power contacts and the second set 136 of power contacts are electrically coupled together to pass power between the set 132 of power contacts and the second set 136 of power contacts. The illustrative wiring adaptor 92 further includes a wiring terminal block 142 that is electrically coupled with the set 134 of communication contacts and the second set 138 of communication contacts. In the example shown, the set 134 of communication contacts and the second set 138 of communication contacts are electrically coupled together to pass one or more communication busses between the set 134 of communication contacts and the second set 138 of communication contacts.

The wiring adaptor 94 includes a set 148 of power contacts and a set 150 of communication contacts. The wiring adaptor 94 also includes a second set 152 of power contacts and a second set 154 of communication contacts. The wiring adaptor 92 is electrically coupled with the wiring adaptor 94 via an electrical conductor 156 (e.g. wires), which extends from the wiring terminal block 140 to a wiring terminal block 144 that is electrically coupled with the set 148 of power contacts and the set 152 of power contacts (which are operatively coupled together). The electrical conductor 156 may include one, two, three or more electrically isolated wires or conductors. The wiring adaptor 92 is also electrically coupled with the wiring adaptor 94 via an electrical conductor 158 (e.g. wires), which extends from the wiring terminal 142 to a wiring terminal 146 that is electrically coupled with the set 150 of communication contacts and the set 154 of communication contacts (which are operatively coupled together).

The IO module 96 includes a set 160 of power contacts and a set 162 of communication contacts that are configured to electrically couple with the set 152 of power contacts and the set 154 of communication contacts, respectively, of the wiring adaptor 94. The IO module 96 also includes a second set 164 of power contacts and a second set 166 of communication contacts. In the example shown, the set 160 of power contacts and the second set 164 of power contacts are electrically coupled together to pass power between the set 160 of power contacts and the second set 164 of power contacts. Also, the set 162 of communication contacts and the second set 166 of communication contacts are electrically coupled together to pass one or more communication busses between the set 162 of communication contacts and the second set 166 of communication contacts.

The IO module 98 includes a set 168 of power contacts and a set 170 of communication contacts that are configured to electrically couple with the second set 164 of power contacts and the second set 166 of communication contacts, respectively, of the IO module 96. The IO module 98 also includes a second set 172 of power contacts and a second set 174 of communication contacts. In the example shown, the set 168 of power contacts and the second set 172 of power contacts are electrically coupled together to pass power between the set 168 of power contacts and the second set 172 of power contacts. Also, the set 170 of communication contacts and the second set 174 of communication contacts are electrically coupled together to pass one or more communication busses between the set 170 of communication contacts and the second set 174 of communication contacts.

The IO module 100 includes a set 176 of power contacts and a set 178 of communication contacts that are configured to electrically couple with the second set 172 of power contacts and the second set 174 of communication contacts, respectively, of the IO module 98. The IO module 100 also includes a second set 180 of power contacts and a second set 182 of communication contacts that in this particular arrangement do not make electrical contact with another device. Rather, the protective cover 102 is added to prevent the second set 180 of power contacts and the second set 182 of communication contacts from making electrical contact with another device, an installer tool or any other object. In the example shown, the set 176 of power contacts and the second set 180 of power contacts are electrically coupled together to pass power between the set 176 of power contacts and the second set 180 of power contacts. Also, the set 178 of communication contacts and the second set 182 of communication contacts are electrically coupled together to pass one or more communication busses between the set 178 of communication contacts and the second set 182 of communication contacts.

FIG. 5 shows a controller 84 that is an RS-485 equipped controller. RS-485 is a two-wire serial bus protocol. It will be appreciated that a 10BASE-T1L (or 10BASE-T1S) equipped controller may be combined with a number of IO modules, using one or more wiring adaptors, in a similar manner. The 10BASE-T1L and 10BASE-T1S) are two-wire Ethernet based point-to-point bus protocols. While RS-485 and TIL are used as examples, it is contemplated that any suitable communication bus may be used. In some cases, two or more different communication busses may be implemented at the same time, such as an RS-485 bus and a TIL bus. For example, in some cases, two of the four contacts 28a-28d (see FIG. 1) may be used to implement the RS-485 bus and the remaining two of the four contacts 28a-28d may be used to implement the TIL bus.

In some cases, when there are electronic devices on two or more distinct DIN rails, the DIN rails may not be in the same room. In some cases, the electronic devices along at least one of the DIN rails may include a separate power supply that powers the devices along that DIN rail, rather than relying on making wired power connections between the devices on each DIN rail, particularly when the DIN rails are separated by a distance.

In some cases, an electrically coupled combination of electronic devices may include one or more devices utilizing a first communication protocol and one or more devices utilizing a second communication protocol. As an example, the first communication protocol may be an RS-485 communication protocol and the second communication protocol may be a TIL or TIS Ethernet communication protocol. In some cases, each of the electronic devices may include a plurality of communication passthroughs, with each communication passthrough extending from a first side of each device to a second side of each device. In some cases, a first subset of the plurality of communication passthroughs within each device may be dedicated to the first communication protocol while a second subset of the plurality of communication passthroughs within each device may be dedicated to the second communication protocol.

In some cases, the wiring adaptors may be specific to a particular communication protocol. For example, the communication wiring terminals on a wiring adaptor configured for the first communication protocol may be electrically coupled, either directly or through circuitry within the wiring adaptor, with the first subset of the plurality of communication passthroughs that are dedicated to the first communication protocol. The communication wiring terminals on a wiring adaptor configured for the second communication protocol may be electrically coupled, either directly or through circuitry within the wiring adaptor, with the second subset of the plurality of communication passthroughs. In some cases, there may be two (or more) communication passthroughs that are dedicated to the first communication protocol and two (or more) different communication passthroughs that are dedicated to the second communication protocol.

Electronic devices that communicate via the first communication protocol and electronic devices that communicate via the second communication protocol may be combined along one or more DIN rails, and may be operably coupled together electrically via the contacts and accompanying power passthroughs and communication passthroughs. In some cases, the communication passthroughs allow for formation of a first communication bus and a second communication bus, where the devices that communicate via the first communication protocol operably couple to the first communication bus and devices that communicate via the second communication protocol operably couple to the second communication bus. In one example, all devices are configured to pass both communication busses through themselves, regardless of which communication protocol a particular device relies upon.

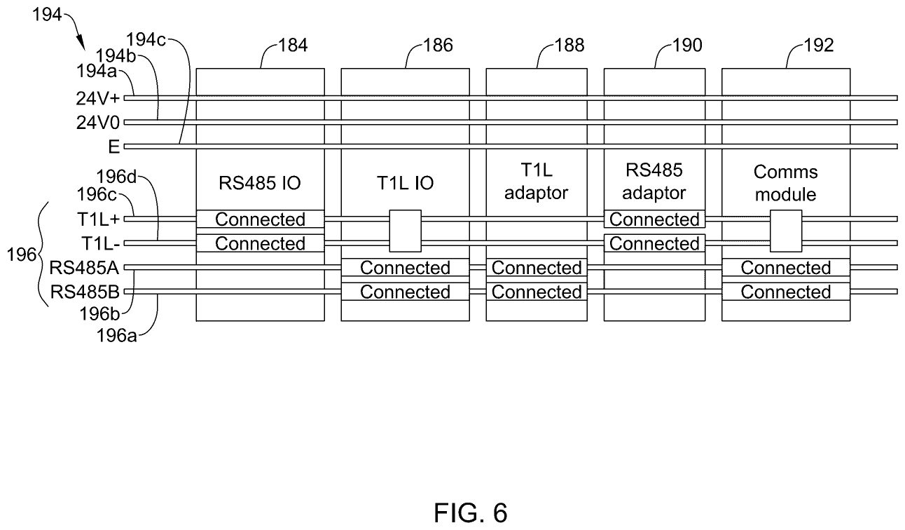

FIG. 6 is a schematic block diagram showing how a first communication bus and a second communication bus are passed through a number of devices, some of which rely upon the first communication bus for communication and some of which rely upon the second communication bus for communication. It will be appreciated that the devices shown are only a portion of the devices that are on the first and second communication busses. In some cases, there will be a controller that is configured to communicate over the first communication bus, using the first communication protocol, and a controller that is configured to communicate over the second communication bus, using the second communication protocol, and which may or may not be able to communicate over the first communication bus.

FIG. 6 shows an RS-485 IO module 184, a TIL IO module 186, a TIL wiring adaptor 188, an RS-485 wiring adaptor 190 and a Comms module 192. Each of the devices 184, 186, 188, 190 and 192 are electrically coupled with power passthroughs 194, individually labeled as 194a, 194b and 194c, and thus are powered by the power passthroughs 194. Each of the devices 184, 184, 188, 190 and 192 pass along a number of communication passthroughs 196. The RS-485 communication passthroughs are individually labeled as 196a and 196b. The TIL communication passthroughs are individually labeled as 196c and 196d. As can be seen, all four of the communication passthroughs pass through each of the devices, thereby extending continuity of the communication busses across all devices. The RS-485 IO module 184 is operably coupled with the RS-485 passthroughs 196a and 196b, and communicates over the RS-485 bus. The RS-485 module 184 does not communicate over the TIL bus, but still includes TIL passthroughs 196c and 196d to extend continuity of the TIL bus to the neighboring device TIL IO module 186.

The TIL IO module 186 is operably coupled with the TIL passthroughs 196c and 196d, and communicates over the TIL bus. The TIL IO module 186 does not communicate over the RS-485 bus, but still includes RS-485 passthroughs 196a and 196b to extend continuity of the RS-485 bus to the neighboring device TIL Wiring Adaptor 188.

The TIL Wiring Adaptor 188 is operably coupled with the TIL passthroughs 196c and 196d, and communicates over the TIL bus. The TIL Wiring Adaptor module 188 does not communicate over the RS-485 bus, but still includes RS-485 passthroughs 196a and 196b to extend continuity of the RS-485 bus to the neighboring device RS485 Adaptor 190. The TIL Wiring Adaptor 188 may include wiring terminals to tap the TIL communication bus and extend the TIL communication bus to another device or set of devices.

The RS485 Wiring Adaptor 190 is operably coupled with the RS-485 passthroughs 196a and 196b, and communicates over the RS-485 bus. The RS485 Wiring Adaptor 190 does not communicate over the TIL bus, but still includes TIL passthroughs 196c and 196d to extend continuity of the T1L bus to the neighboring device COMMs Module 192. The RS485 Wiring Adaptor 190 may include wiring terminals to tap the RS-485 communication bus and extend the RS-485 communication bus to another device or set of devices.

The Comms module 192, which relies upon the TIL communication protocol, is operably coupled to the TIL passthroughs 196c and 196d and communicates over the TIL bus. The Comms module 192 does not communicate over the RS-485 bus, but still includes RS-485 passthroughs 196a and 196b to extend continuity of the RS-485 bus to a neighboring device (if any).

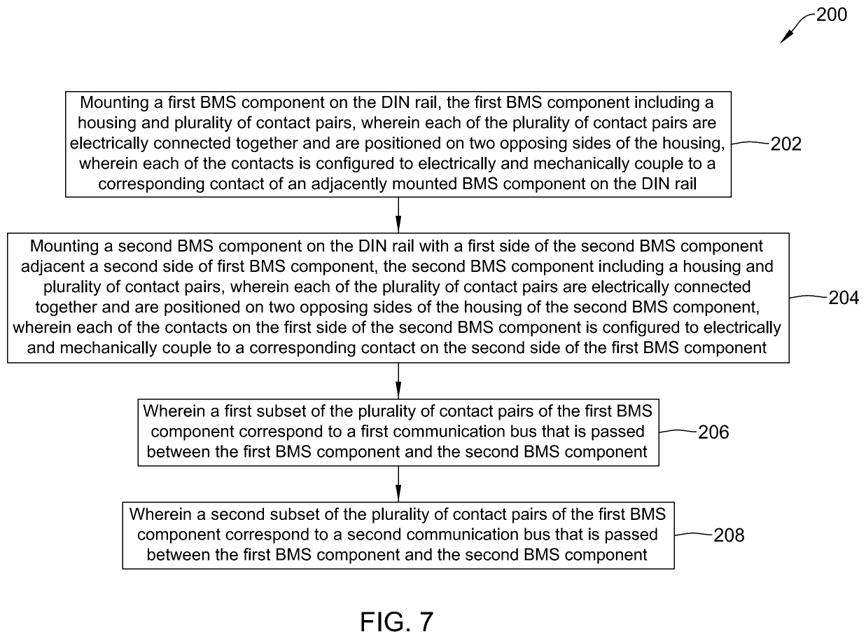

FIG. 7 is a flow diagram showing an illustrative method 200 for mounting a plurality of building management system (BMS) components on a DIN rail. The method 200 includes mounting a first BMS component on the DIN rail, the first BMS component including a housing and plurality of contact pairs, wherein each of the plurality of contact pairs are electrically connected together and are positioned on two opposing sides of the housing, wherein each of the contacts is configured to electrically and mechanically couple to a corresponding contact of an adjacently mounted BMS component on the DIN rail, as indicated at block 202. A second BMS component is mounted on the DIN rail with a first side of the second BMS component adjacent a second side of first BMS component, the second BMS component including a housing and plurality of contact pairs, wherein each of the plurality of contact pairs are electrically connected together and are positioned on two opposing sides of the housing of the second BMS component, wherein each of the contacts on the first side of the second BMS component is configured to electrically and mechanically couple to a corresponding contact on the second side of the first BMS component, as indicated at block 204.

In some cases, a first subset of the plurality of contact pairs of the first BMS component correspond to a first communication bus that is passed between the first BMS component and the second BMS component, as indicated at block 206. In some cases, a second subset of the plurality of contact pairs of the first BMS component correspond to a second communication bus that is passed between the first BMS component and the second BMS component, as indicated at block 208.

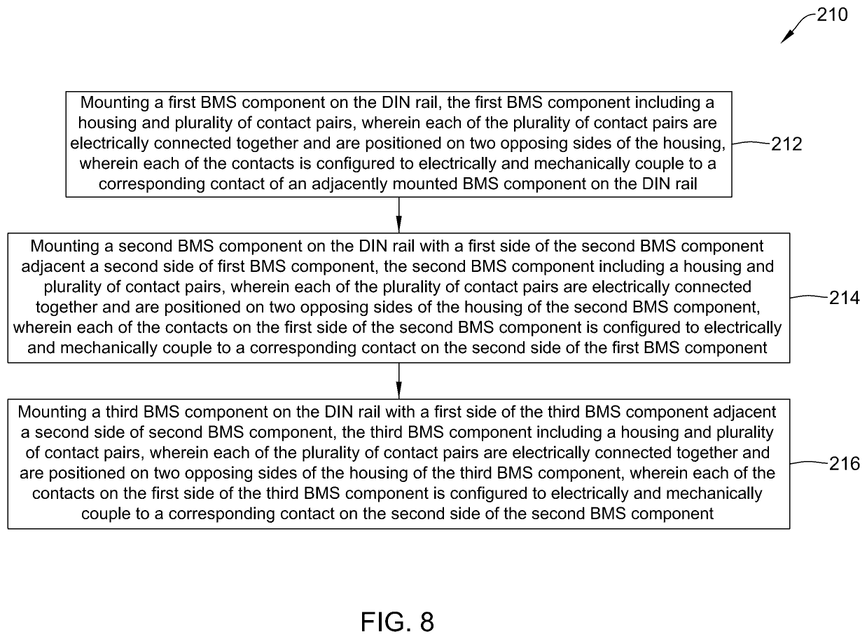

FIG. 8 is a flow diagram showing an illustrative method 210 for mounting a plurality of building management system (BMS) components on a DIN rail. The method 210 includes mounting a first BMS component on the DIN rail, the first BMS component including a housing and plurality of contact pairs, wherein each of the plurality of contact pairs are electrically connected together and are positioned on two opposing sides of the housing, wherein each of the contacts is configured to electrically and mechanically couple to a corresponding contact of an adjacently mounted BMS component on the DIN rail, as indicated at block 212. A second BMS component is mounted on the DIN rail with a first side of the second BMS component adjacent a second side of first BMS component, the second BMS component including a housing and plurality of contact pairs, wherein each of the plurality of contact pairs are electrically connected together and are positioned on two opposing sides of the housing of the second BMS component, wherein each of the contacts on the first side of the second BMS component is configured to electrically and mechanically couple to a corresponding contact on the second side of the first BMS component, as indicated at block 214.

In some cases, a first subset of the plurality of contact pairs of the first BMS component correspond to a first communication bus that is passed between the first BMS component and the second BMS component and a second subset of the plurality of contact pairs of the first BMS component correspond to a second communication bus that is passed between the first BMS component and the second BMS component. In some cases, the method 210 may also include mounting a third BMS component on the DIN rail with a first side of the third BMS component adjacent a second side of second BMS component, the third BMS component including a housing and plurality of contact pairs, wherein each of the plurality of contact pairs are electrically connected together and are positioned on two opposing sides of the housing of the third BMS component, wherein each of the contacts on the first side of the third BMS component is configured to electrically and mechanically couple to a corresponding contact on the second side of the second BMS component, as indicated at block 216.

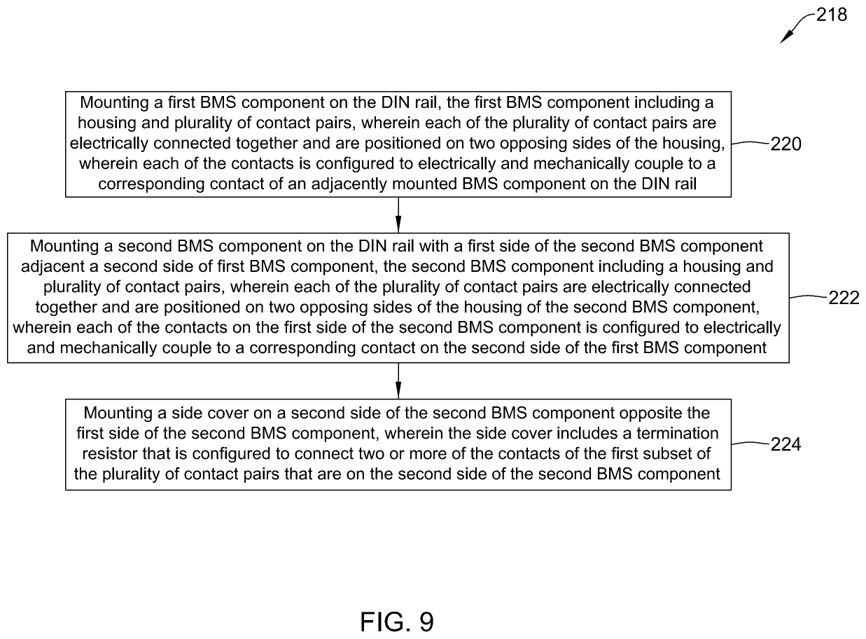

FIG. 9 is a flow diagram showing an illustrative method 218 for mounting a plurality of building management system (BMS) components on a DIN rail. The method 218 includes mounting a first BMS component on the DIN rail, the first BMS component including a housing and plurality of contact pairs, wherein each of the plurality of contact pairs are electrically connected together and are positioned on two opposing sides of the housing, wherein each of the contacts is configured to electrically and mechanically couple to a corresponding contact of an adjacently mounted BMS component on the DIN rail, as indicated at block 220. A second BMS component is mounted on the DIN rail with a first side of the second BMS component adjacent a second side of first BMS component, the second BMS component including a housing and plurality of contact pairs, wherein each of the plurality of contact pairs are electrically connected together and are positioned on two opposing sides of the housing of the second BMS component, wherein each of the contacts on the first side of the second BMS component is configured to electrically and mechanically couple to a corresponding contact on the second side of the first BMS component, as indicated at block 222.

In some cases, a first subset of the plurality of contact pairs of the first BMS component correspond to a first communication bus that is passed between the first BMS component and the second BMS component, and a second subset of the plurality of contact pairs of the first BMS component correspond to a second communication bus that is passed between the first BMS component and the second BMS component. In some cases, the method 218 may further include mounting a side cover on a second side of the second BMS component opposite the first side of the second BMS component, wherein the side cover includes a termination resistor that is configured to connect two or more of the contacts of the first subset of the plurality of contact pairs that are on the second side of the second BMS component, as indicated at block 224.

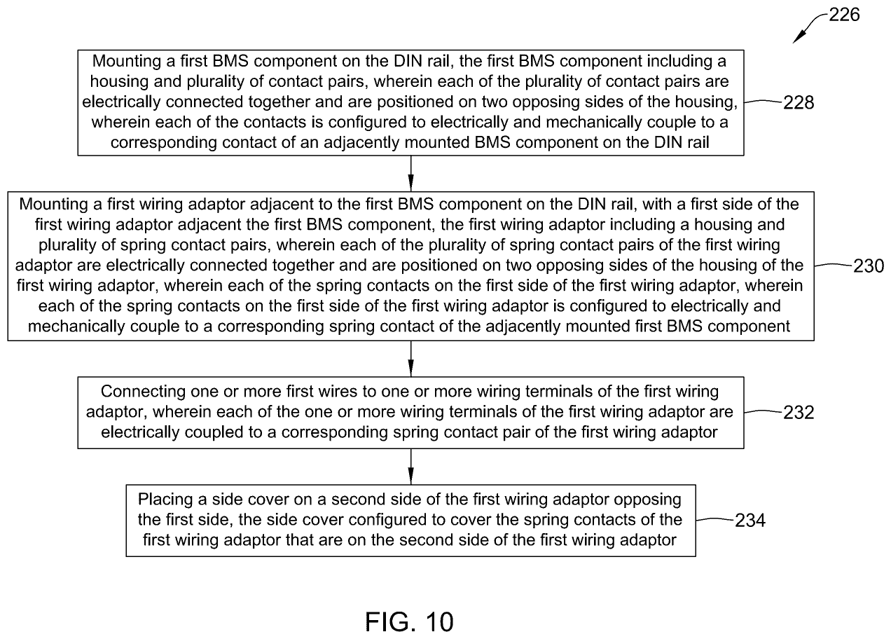

FIG. 10 is a flow diagram showing an illustrative method 226 for mounting a plurality of building management system (BMS) components on a DIN rail. The method 226 includes mounting a first BMS component on the DIN rail, the first BMS component including a housing and plurality of spring contact pairs, wherein each of the plurality of spring contact pairs are electrically connected together and are positioned on two opposing sides of the housing, wherein each of the spring contacts is configured to electrically and mechanically couple to a corresponding spring contact of an adjacently mounted BMS component on the DIN rail, as indicated at block 228. A first wiring adaptor is mounted adjacent to the first BMS component on the DIN rail, with a first side of the first wiring adaptor adjacent the first BMS component, the first wiring adaptor including a housing and plurality of spring contact pairs, wherein each of the plurality of spring contact pairs of the first wiring adaptor are electrically connected together and are positioned on two opposing sides of the housing of the first wiring adaptor, wherein each of the spring contacts on the first side of the first wiring adaptor is configured to electrically and mechanically couple to a corresponding spring contact of the adjacently mounted first BMS component, as indicated at block 230.

One or more first wires may be connected to one or more wiring terminals of the first wiring adaptor, wherein each of the one or more wiring terminals of the first wiring adaptor are electrically coupled to a corresponding spring contact pair of the first wiring adaptor, as indicated at block 232. In some cases, the method 226 may further include placing a side cover on a second side of the first wiring adaptor opposing the first side, the side cover configured to cover the spring contacts of the first wiring adaptor that are on the second side of the first wiring adaptor, as indicated at block 234.

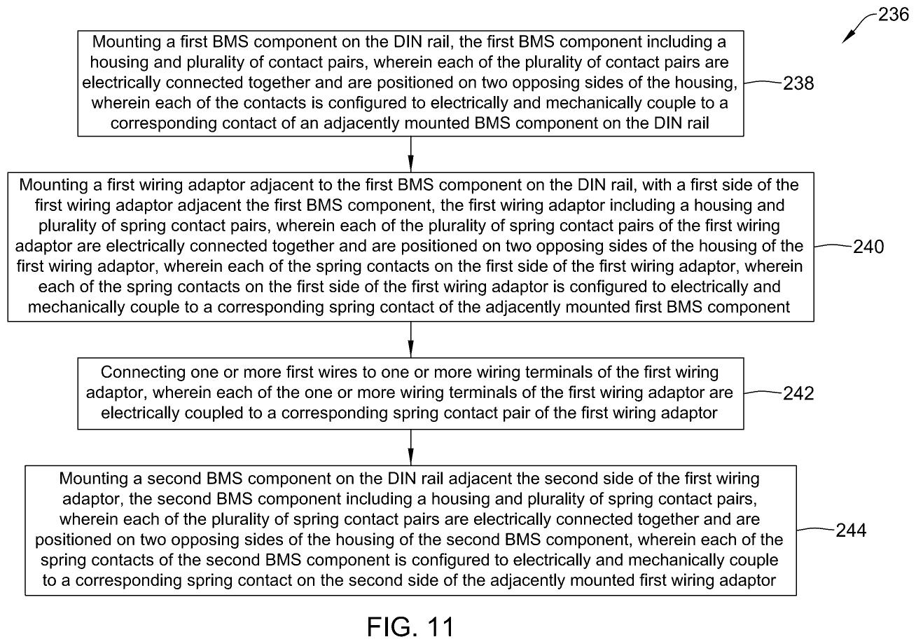

FIG. 11 is a flow diagram showing an illustrative method 236 for mounting a plurality of building management system (BMS) components on a DIN rail. The method 236 includes mounting a first BMS component on the DIN rail, the first BMS component including a housing and plurality of spring contact pairs, wherein each of the plurality of spring contact pairs are electrically connected together and are positioned on two opposing sides of the housing, wherein each of the spring contacts is configured to electrically and mechanically couple to a corresponding spring contact of an adjacently mounted BMS component on the DIN rail, as indicated at block 238. A first wiring adaptor is mounted adjacent to the first BMS component on the DIN rail, with a first side of the first wiring adaptor adjacent the first BMS component, the first wiring adaptor including a housing and plurality of spring contact pairs, wherein each of the plurality of spring contact pairs of the first wiring adaptor are electrically connected together and are positioned on two opposing sides of the housing of the first wiring adaptor, wherein each of the spring contacts on the first side of the first wiring adaptor is configured to electrically and mechanically couple to a corresponding spring contact of the adjacently mounted first BMS component, as indicated at block 240.

One or more first wires may be connected to one or more wiring terminals of the first wiring adaptor, wherein each of the one or more wiring terminals of the first wiring adaptor are electrically coupled to a corresponding spring contact pair of the first wiring adaptor, as indicated at block 242. One or more second wires may be connected to a second wiring adaptor that is mounted to another DIN rail. In some cases, the method 236 may further include mounting a second BMS component on the DIN rail adjacent the second side of the first wiring adaptor, the second BMS component including a housing and plurality of spring contact pairs, wherein each of the plurality of spring contact pairs are electrically connected together and are positioned on two opposing sides of the housing of the second BMS component, wherein each of the spring contacts of the second BMS component is configured to electrically and mechanically couple to a corresponding spring contact on the second side of the adjacently mounted first wiring adaptor, as indicated at block 244.

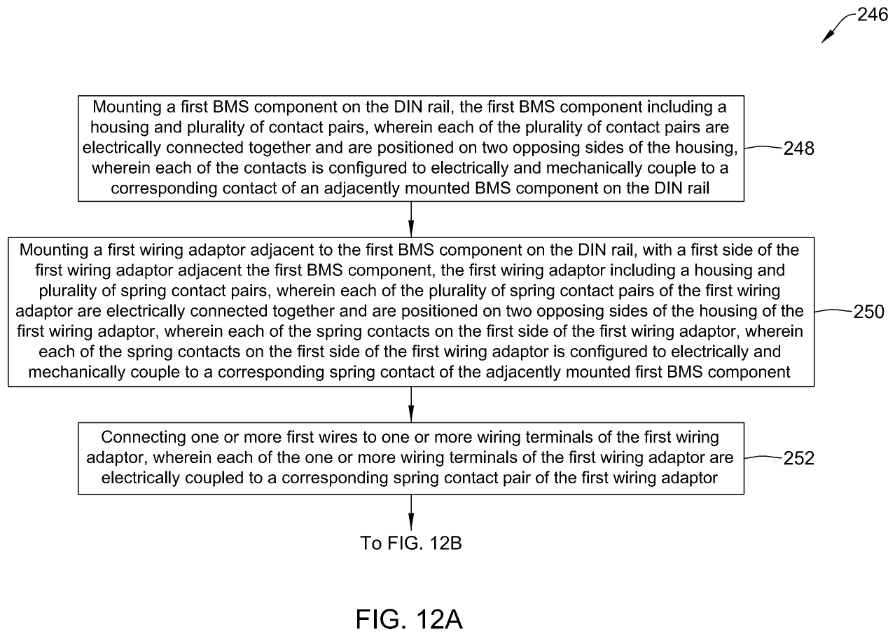

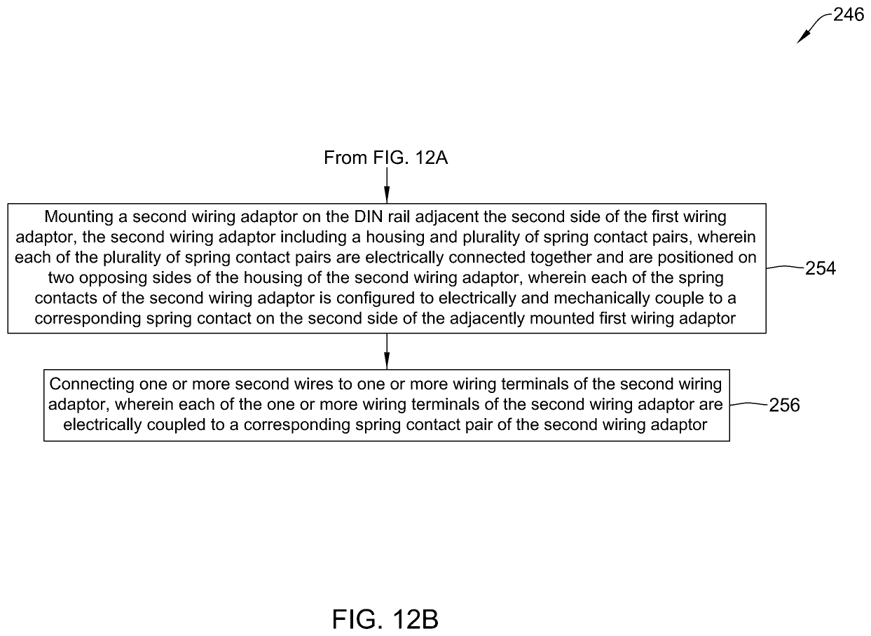

FIGS. 12A and 12B are flow diagrams that together show an illustrative method 246 for mounting a plurality of building management system (BMS) components on a DIN rail. The method 246 includes mounting a first BMS component on the DIN rail, the first BMS component including a housing and plurality of spring contact pairs, wherein each of the plurality of spring contact pairs are electrically connected together and are positioned on two opposing sides of the housing, wherein each of the spring contacts is configured to electrically and mechanically couple to a corresponding spring contact of an adjacently mounted BMS component on the DIN rail, as indicated at block 248. A first wiring adaptor is mounted adjacent to the first BMS component on the DIN rail, with a first side of the first wiring adaptor adjacent the first BMS component, the first wiring adaptor including a housing and plurality of spring contact pairs, wherein each of the plurality of spring contact pairs of the first wiring adaptor are electrically connected together and are positioned on two opposing sides of the housing of the first wiring adaptor, wherein each of the spring contacts on the first side of the first wiring adaptor is configured to electrically and mechanically couple to a corresponding spring contact of the adjacently mounted first BMS component, as indicated at block 250.

One or more first wires may be connected to one or more wiring terminals of the first wiring adaptor, wherein each of the one or more wiring terminals of the first wiring adaptor are electrically coupled to a corresponding spring contact pair of the first wiring adaptor, as indicated at block 252. In some cases, and as continued on FIG. 12B, the method 246 may further include mounting a second wiring adaptor on the DIN rail adjacent the second side of the first wiring adaptor, the second wiring adaptor including a housing and plurality of spring contact pairs, wherein each of the plurality of spring contact pairs are electrically connected together and are positioned on two opposing sides of the housing of the second wiring adaptor, wherein each of the spring contacts of the second wiring adaptor is configured to electrically and mechanically couple to a corresponding spring contact on the second side of the adjacently mounted first wiring adaptor, as indicated at block 254.

One or more second wires may be connected to one or more wiring terminals of the second wiring adaptor, wherein each of the one or more wiring terminals of the second wiring adaptor are electrically coupled to a corresponding spring contact pair of the second wiring adaptor, as indicated at block 256. In some cases, the one or more first wires connected to the one or more wiring terminals of the first wiring adaptor provide access to a first communication bus carried by two or more of the plurality of spring contact pairs of the first BMS component and the one or more second wires connected to the one or more wiring terminals of the second wiring adaptor provide access to a second communication bus carried by two or more of the plurality of spring contact pairs of the first BMS component.

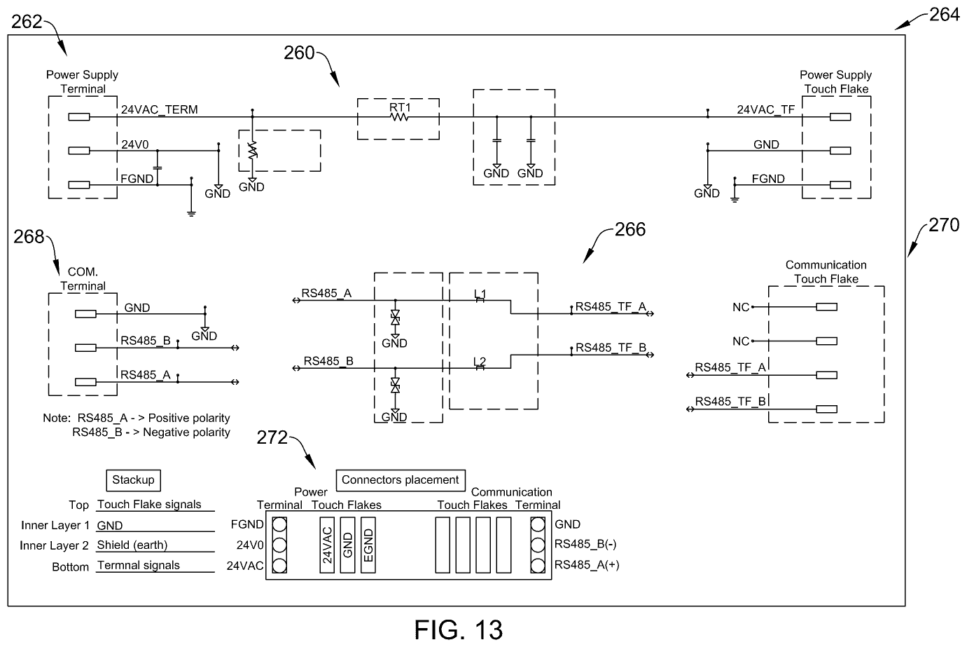

FIG. 13 is an electrical schematic diagram of a wiring adapter that extends the continuity of a first communication bus (RS-485 bus) through touch flake pairs while providing wiring terminals to access the first communication bus. In particular, FIG. 13 shows how a number of power terminals of a power supply terminal block 262 are connected to the power passthroughs and corresponding power supply touch flakes (contact) 264. As can be seen, in this example, the power touch flakes 264 include a 24 VAC touch flake, a ground touch flake (GND) and a chasses ground touch flake (FGND). The 24 VAC terminal of the power supply terminal block 262 is connected to the 24 VAC touch flake through a current limiter and a filter (Protection against burst). The ground terminal and the chassis ground terminal of the power supply terminal block 262 are connected directly to the ground touch flake (GND) and a chasses ground touch flake (FGND), respectively, as shown.

FIG. 13 also shows how RS-485 bus terminals of a RS-485 communication terminal block 268 are connected to the RS-485 passthroughs and corresponding RS-485 touch flakes (contacts) 270. As can be seen, in this example, the RS-485 touch flakes (contacts) 270 include an RS485-TF-A touch flake and an RS485-TF-B touch flake. The remaining two touch flakes are used to support the TIL bus, and are not connected to the RS-485 communication terminal block 268. A GND terminal of the RS-485 communication terminal block 268 is connected to ground of the wiring adapter. The RS485-A terminal and the RS-485-B terminal of the RS-485 communication terminal block 268 are connected to the RS485-TF-A touch flake and the RS485-TF-A touch flake, respectively, via a Transient Overvoltage protection circuit and a Conducted Immunity and Emissions circuit. The power passthroughs and communications passthrough between the touch flake pairs on opposing sides of the wiring adapter are not explicitly shown. The wiring terminal and touch flake placement are schematically shown at 272.

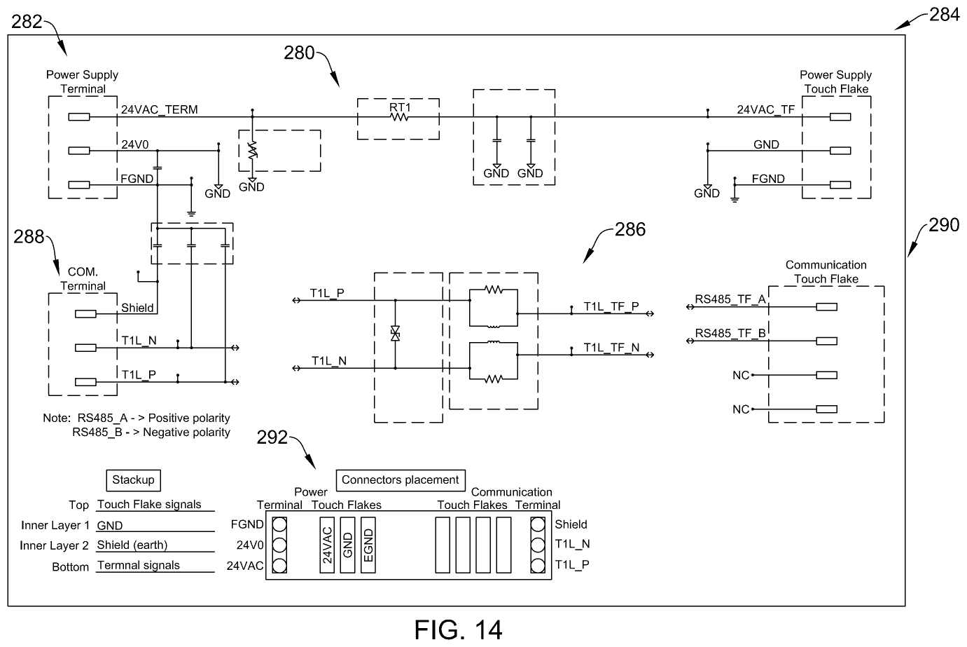

FIG. 14 is an electrical schematic diagram of a wiring adapter that extends the continuity of a second communication bus (TIL bus) through touch flake pairs while providing wiring terminals to access the second communication bus. In particular, FIG. 14 shows how a number of power terminals of a power supply terminal block 282 are connected to the power passthroughs and corresponding power supply touch flakes (contact) 284. As can be seen, in this example, the power touch flakes 284 include a 24 VAC touch flake, a ground touch flake (GND) and a chasses ground touch flake (FGND). The 24 VAC terminal of the power supply terminal block 282 is connected to the 24 VAC touch flake through a transient overvoltage protection circuit, a current limiter and a filter (Protection against burst). The ground terminal and the chassis ground terminal of the power supply terminal block 282 are connected directly to the ground touch flake (GND) and a chasses ground touch flake (FGND), respectively, as shown.

FIG. 14 also shows how RIL bus terminals of a TIL communication terminal block 288 are connected to the TIL passthroughs and corresponding TIL touch flakes (contacts) 290. As can be seen, in this example, the TIL touch flakes (contacts) 290 include an TIL-TF-P touch flake and an TIL-TF-N touch flake. The remaining two touch flakes are used to support the RS-485 bus, and are not connected to the TIL communication terminal block 288. A GND terminal of the TL1 communication terminal block 288 is connected to ground of the wiring adapter through a filtering capacitor. The TIL-P terminal and the TIL-N terminal of the T1L communication terminal block 288 are connected to the TIL-TF-P touch flake and the TIL-TF-N touch flake, respectively, via a Transient Overvoltage protection circuit and a Common Mode Choke and damping circuit. The power passthroughs and communications passthrough between the touch flake pairs on opposing sides of the wiring adapter are not explicitly shown. The wiring terminal and touch flake placement are schematically shown at 272.

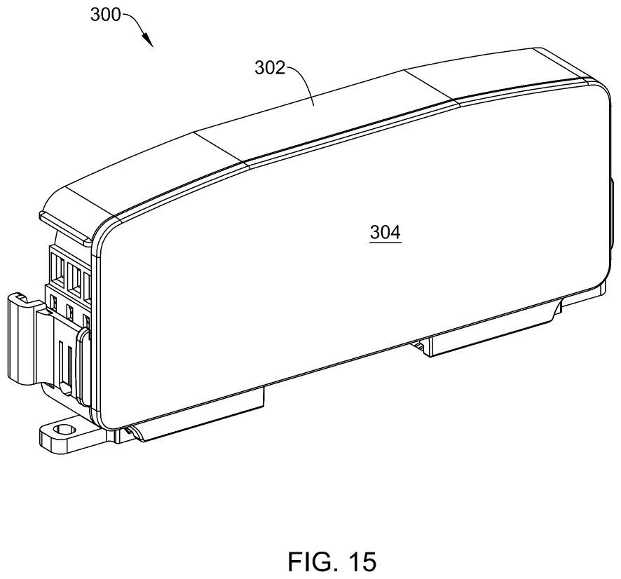

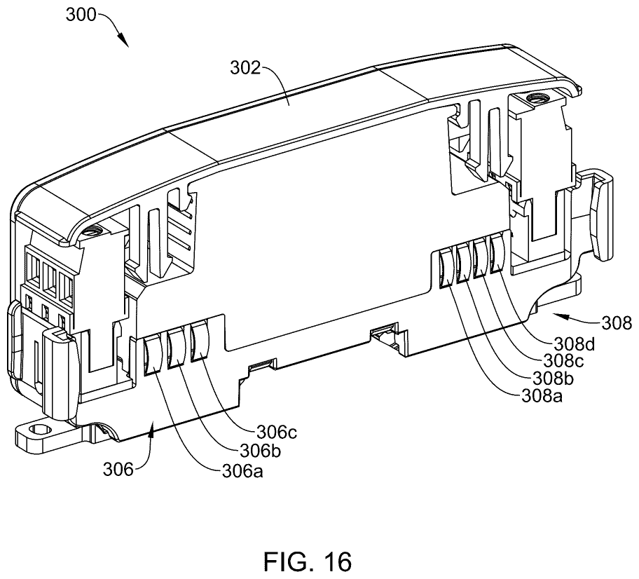

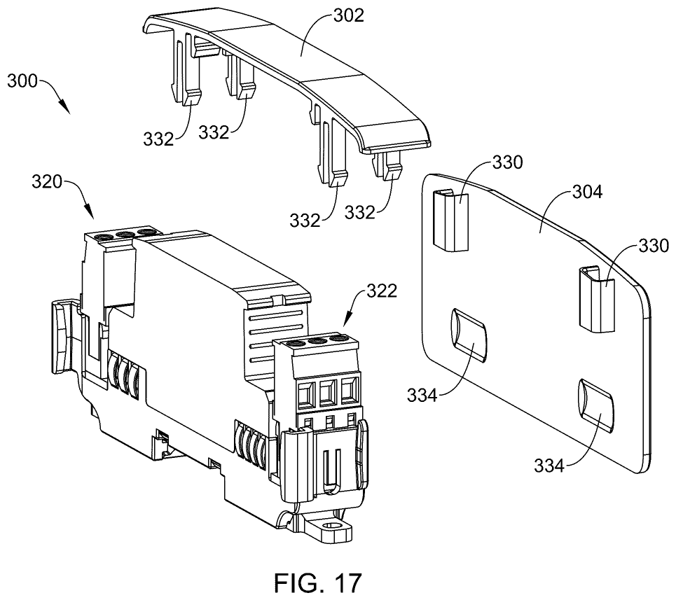

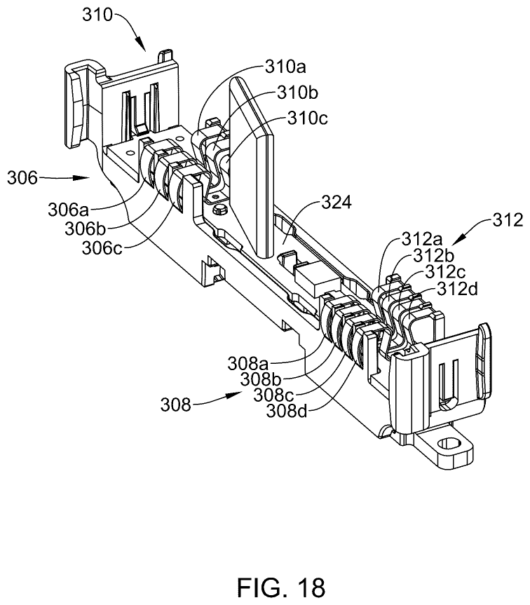

FIG. 15 is a first side perspective of an illustrative wiring adaptor 300 and FIG. 16 is a second side perspective view of the illustrative wiring adaptor 300. The wiring adaptor 300 may be considered as an example of any of the wiring adaptor 60, the wiring adaptor 68, the wiring adaptor 92, the wiring adaptor 94, the TIL adaptor 188 or the RS-485 adaptor 190. FIG. 17 is a partially exploded perspective view of the illustrative wiring adaptor 300 while FIG. 18 is a perspective view of the illustrative wiring adaptor 300 with several components removed to reveal internal details.

The illustrative wiring adaptor 300 includes a removable top cover 302 and a removable side cover 304. As shown, the side cover 304 is mounted on a right side (in the illustrated orientation of FIG. 15) of the wiring adaptor 300. The side cover 304 may be removed from the wiring adaptor 300 and placed on the opposing side (e.g. left side), depending on which side of the wiring adaptor 300 will face another electrical device and which side of the wiring adaptor 300 will not. If the wiring adaptor 300 is going to be disposed between electrical devices on both side of the wiring adaptor 300, then the side cover 304 will not be used at all. In some cases, the top cover 302 may be removed in order to attach or detach the side cover 304, and then the top cover 302 may be replaced on the wiring adaptor 300.

In some cases, since the wiring adaptor 300 may have internal wiring or other circuitry that defines the wiring adaptor 300 as an RS-485 wiring adaptor, such as because the wiring terminals are operably coupled to the RS-845 communication passthroughs, then the top cover 302 may include indicia indicating that the wiring adaptor 300 is configured as an RS-485 wiring adaptor. In cases in which the wiring adaptor 300 has internal wiring or other circuitry that defines the wiring adaptor 300 as a TIL wiring adaptor, such as because the wiring terminals are operably coupled to the TIL communication passthroughs, then the top cover 302 may include indicia indicating that the wiring adaptor 300 is configured as a TIL wiring adaptor.

The illustrative wiring adaptor 300 includes a first set of power contacts 306, individually labeled as 306a, 306b and 306c. The power contacts 306, as seen in FIG. 18, are coupled with, or integrally formed with, a first set of electrical connectors 310, individually labeled as 310a, 310b, and 310c. The first set of electrical connectors 310 are coupled with, or integrally formed with, a second set of power contacts (not explicitly shown in FIG. 18) on an opposing side of the wiring adaptor 300. The second set of power contacts may be a mirror image of the first set of power contacts 306 but on the opposing side of the wiring adaptor 300.

The illustrative wiring adaptor 300 includes a first set of communication contacts 308, individually labeled as 308a, 308b, 308c and 308d. The communication contacts 308, as seen in FIG. 18, are coupled with, or integrally formed with, a second set of electrical connectors 312, individually labeled as 312a, 312b, 312c and 312d. The second set of electrical connectors are coupled with, or integrally formed with, a second set of communication contacts (not explicitly shown in FIG. 18) on an opposing side of the wiring adaptor 300. The second set of communication contacts may be a mirror image of the first set of communication contacts 308 but on the opposing side of the wiring adaptor 300.

As seen for example in FIG. 17, the illustrative wiring adaptor 300 includes a wiring terminal block 320 and a wiring terminal block 322. In some cases, the wiring terminal block 320 is electrically coupled with the power passthroughs and the wiring terminal block 322 is electrically coupled with the communication passthroughs. The wiring adaptor 300 may include a printed circuit board 324 (see FIG. 18). FIG. 17 also shows how the top cover 302 and the side cover 304 interact. The side cover 304 includes mounting features 330 and the top cover 302 includes mounting features 332. The two mounting features 330 on the side cover 304 are configured to accommodate two of the mounting features 332 on the top cover 302. Depending on which side of the wiring adaptor 300 the side cover 304 has been disposed, either the mounting features 332 on a first side of the top cover 302 or the mounting features 332 on a second side of the top cover 302 will engage the mounting features 330 on the side cover 304. The side cover 304 also includes recesses 334 that are configured to accommodate the power contacts (e.g. touch flakes) 306 (or the corresponding power contacts on the opposing side) and the communication contacts (e.g. touch flakes) 308 (or the corresponding communication contacts on the opposing side).

Those skilled in the art will recognize that the present disclosure may be manifested in a variety of forms other than the specific embodiments described and contemplated herein. Accordingly, departure in form and detail may be made without departing from the scope and spirit of the present disclosure as described in the appended claims.

What is claimed is:

1. An electronic device configured for use with neighboring electronic devices mounted on a DIN rail for use in controlling at least part of a Building Management System (BMS), the electronic device comprising:
a housing;
a plurality of communication passthroughs extending between two opposing sides of the housing, each of the plurality of communication passthroughs including a contact disposed on each of the two opposing side of the housing, wherein each of the contacts is configured to electrically and mechanically couple to a corresponding contact of a neighboring electronic device on the DIN rail;
wherein a first subset of the plurality of communication passthroughs collectively pass a first communication bus between the two opposing sides of the housing; and
wherein a second subset of the plurality of communication passthroughs collectively pass a second communication bus between the two opposing sides of the housing.

2. The electronic device of claim 1, further comprising a controller that is configured to communicate over the first communication bus.

3. The electronic device of claim 2, wherein the controller is not configured to communicate over the second communication bus.

4. The electronic device of claim 2, wherein the controller is configured to communicate over the second communication bus.

5. The electronic device of claim 1, wherein:
the first subset of the plurality of communication passthroughs comprises a first one of the plurality of communication passthroughs and a second one of the plurality of communication passthroughs; and
the second subset of the plurality of communication passthroughs comprises a third one of the plurality of communication passthroughs and a fourth one of the plurality of communication passthroughs.

6. The electronic device of claim 5, wherein the first communication bus operates in accordance with a first communication protocol and the second communication bus operates in accordance with a second communication protocol, wherein the first communication protocol is a serial bus protocol and the second communication protocol is an Ethernet protocol.

7. The electronic device of claim 6, wherein the first communication protocol is a RS-485 bus protocol and the second communication protocol is a TIL or a TIS Ethernet protocol.

8. The electronic device of claim 1, further comprising:
a plurality of power passthroughs extending between the two opposing sides of the housing, each of the plurality of power passthroughs include a contact disposed on each of the two opposing side of the housing, wherein each of the contacts is configured to electrically and mechanically couple to a corresponding contact of the neighboring electronic device on the DIN rail.

9. The electronic device of claim 8, wherein the plurality of power passthroughs include a hot power passthrough and a ground power passthrough.

10. The electronic device of claim 9, wherein the plurality of power passthroughs include a chassis ground power passthrough.

11. The electronic device of claim 1, wherein each of the plurality of communication passthroughs comprise a conductive metal bridge that is configured to electrically connect and form the contacts on each of the two opposing sides of the housing that correspond to the respective communication passthrough.

12. The electronic device of claim 11, wherein each of at least some of the plurality of communication passthroughs comprise one or more electrical components operatively coupled to the corresponding conductive metal bridge to provide transient overvoltage protection to the corresponding communication passthrough.

13. The electronic device of claim 11, wherein each of at least some of the plurality of communication passthroughs comprise one or more electrical components operatively coupled to the corresponding conductive metal bridge to provide Electro Magnetic Interference (EMI) suppression to the corresponding communication passthrough.

14. The electronic device of claim 1, wherein the housing is configured to releasably receive a side cover on a first one of the two opposing sides of the housing, wherein the side cover includes a termination resistor that is configured to connect two or more of the contacts of the first subset of the plurality of communication passthroughs on the first one of the two opposing sides of the housing.

15. The electronic device of claim 1, wherein the electronic device comprises one of a controller module, an I/O module or a wiring adapter module.

16. A method for mounting a plurality of building management system (BMS) components on a DIN rail, the method comprising:
mounting a first BMS component on the DIN rail, the first BMS component including a housing and plurality of contact pairs, wherein each of the plurality of contact pairs are electrically connected together and are positioned on two opposing sides of the housing, wherein each of the contacts is configured to electrically and mechanically couple to a corresponding contact of an adjacently mounted BMS component on the DIN rail;
mounting a second BMS component on the DIN rail with a first side of the second BMS component adjacent a second side of first BMS component, the second BMS component including a housing and plurality of contact pairs, wherein each of the plurality of contact pairs are electrically connected together and are positioned on two opposing sides of the housing of the second BMS component, wherein each of the contacts on the first side of the second BMS component is configured to electrically and mechanically couple to a corresponding contact on the second side of the first BMS component;
wherein a first subset of the plurality of contact pairs of the first BMS component correspond to a first communication bus that is passed between the first BMS component and the second BMS component; and
wherein a second subset of the plurality of contact pairs of the first BMS component correspond to a second communication bus that is passed between the first BMS component and the second BMS component.

17. A method of claim 16, further comprising:
mounting a third BMS component on the DIN rail with a first side of the third BMS component adjacent a second side of second BMS component, the third BMS component including a housing and plurality of contact pairs, wherein each of the plurality of contact pairs are electrically connected together and are positioned on two opposing sides of the housing of the third BMS component, wherein each of the contacts on the first side of the third BMS component is configured to electrically and mechanically couple to a corresponding contact on the second side of the second BMS component.

18. The method of claim 16 further comprising mounting a side cover on a second side of the second BMS component opposite the first side of the second BMS component, wherein the side cover includes a termination resistor that is configured to connect two or more of the contacts of the first subset of the plurality of contact pairs that are on the second side of the second BMS component.

19. An electronic device configured for use with neighboring electronic devices mounted on a DIN rail in order to maintain a plurality of communication buses through the electronic device, the electronic device comprising:
a housing configured to be mountable next to a neighboring electronic device on a DIN rail;
a plurality of power passthroughs extending through the housing and including contacts disposed on two opposing sides of the housing such that the contacts are configured to electrically coupled with contacts disposed on one or more sides of a neighboring electronic device in order to maintain power between the electronic device and the neighboring electronic device; and
a plurality of communication passthroughs extending through the housing and including contacts disposed on the two opposing sides of the housing such that the contacts are configured to electrically couple with contacts disposed on one or more sides of the neighboring electronic device in order to maintain a plurality of communication busses between the electronic device the neighboring electronic device.

20. The electronic device of claim 19, wherein the plurality of communication busses include a first communication bus that operates in accordance with a first communication protocol and a second communication bus that operates in accordance with a second communication protocol, wherein the first communication protocol is a serial bus protocol and the second communication protocol is an Ethernet protocol.
